(19) United States
(12) Patent Application Publication
(10) Pub. No.: US 2026/0011559 A1
(43) Pub. Date: Jan. 8, 2026

(54) WAFER PROCESSING METHOD

(71) Applicant: UNITED MICROELECTRONICS CORP., Hsin-Chu City (TW)

(72) Inventors: Ang Chan, Taipei City (TW); Hsin-Jung Liu, Pingtung County (TW); Chau-Chung Hou, Kaohsiung City (TW); Jhih-Yuan Chen, Kaohsiung City (TW); Wei-Xin Gao, Tainan City (TW); Hsiang-Chi Chien, Pingtung County (TW)

(73) Assignee: UNITED MICROELECTRONICS CORP., Hsin-Chu City (TW)

(21) Appl. No.: 18/788,064

(22) Filed: Jul. 29, 2024

(30) Foreign Application Priority Data
Jul. 2, 2024 (TW) 113124607

(51) Int. Cl. H01L 21/268; H01L 21/304; H01L 23/00

(52) U.S. Cl. CPC H01L 21/268; H01L 21/304; H01L 24/80; H01L 2224/80895; H01L 2224/80896

(57) ABSTRACT

A wafer processing method is disclosed. A second wafer is bonded to a first wafer. An undercut region is formed along the periphery of a front surface of the second wafer. A grinding process is performed on a back surface of the second wafer, thereby thinning the second wafer to a predetermined thickness.

### BACKGROUND OF THE INVENTION

### 1. Field of the Invention

The present invention relates to the field of semiconductor technology, and in particular to an improved wafer processing method.

### 2. Description of the Prior Art

Wafer-to-wafer hybrid bonding is a technique used in 3D integrated circuit (IC) fabrication. It allows for the stacking of multiple wafers vertically, creating devices with greater functionality and miniaturization compared to traditional planar circuits. After the wafers are bonded together, one of the wafers is thinned from the back side thereof to a desired thickness by backside grinding. To eliminate imperfections and inconsistencies along the wafer edge, the wafers are further subjected to a wafer edge trimming process to remove an annular portion (about 2.8 mm wide) along the outer periphery of the wafers to a selected depth.

During wafer edge trimming process, mechanical stresses are induced at the wafer edge due to the cutting forces. These stresses can cause microcracks to form and propagate, leading to chipping. The chipping at the wafer edge may cause reduced yield. Further, the wafer edge trimming process employs multi-stage cutting process that uses different combinations of feed rates and processing time periods. Therefore, the wafer edge trimming process is time-consuming, which results in a low throughput.

### SUMMARY OF THE INVENTION

It is one object of the present invention to provide an improved wafer processing method to solve the deficiencies or shortcomings of the existing technology.

One aspect of the invention provides a wafer processing method including the steps of bonding a second wafer to a first wafer; forming an undercut region along a periphery of a front surface of the second wafer; and subjecting a rear surface of the second wafer to a grinding process, thereby thinning the second wafer to a pre-determined thickness.

According to some embodiments, the undercut region has a width of less than 2.8 mm.

According to some embodiments, the undercut region has a sectional width of 10-200 micrometers.

According to some embodiments, the undercut region has a sectional length of 20-200 micrometers.

According to some embodiments, the undercut region is formed by performing a stealth laser dicing process.

According to some embodiments, a laser beam used during the stealth laser dicing process is focused at a region adjacent the front surface of the second wafer, thereby forming the undercut region.

According to some embodiments, the undercut region is formed by performing a lateral wafer edge cutting process.

According to some embodiments, the lateral wafer edge cutting process uses a diamond blade to cut the periphery of the front surface of second wafer.

According to some embodiments, the second wafer is bonded to the first wafer through hybrid bonding.

According to some embodiments, the pre-determined thickness is less than 100 micrometers.

The method of the present invention is composed of simplified processing steps, which can avoid the problem of particulate contamination, and can have a higher yield. In addition, using stealth laser cutting or lateral wafer edge cutting to form a smaller undercut region can reduce the problem of wafer edge chipping and enable a single wafer to produce more good dies.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 are schematic diagrams showing a wafer processing method according to an embodiment of the present invention.

FIG. 5 to FIG. 6 are schematic diagrams showing a wafer processing method according to another embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

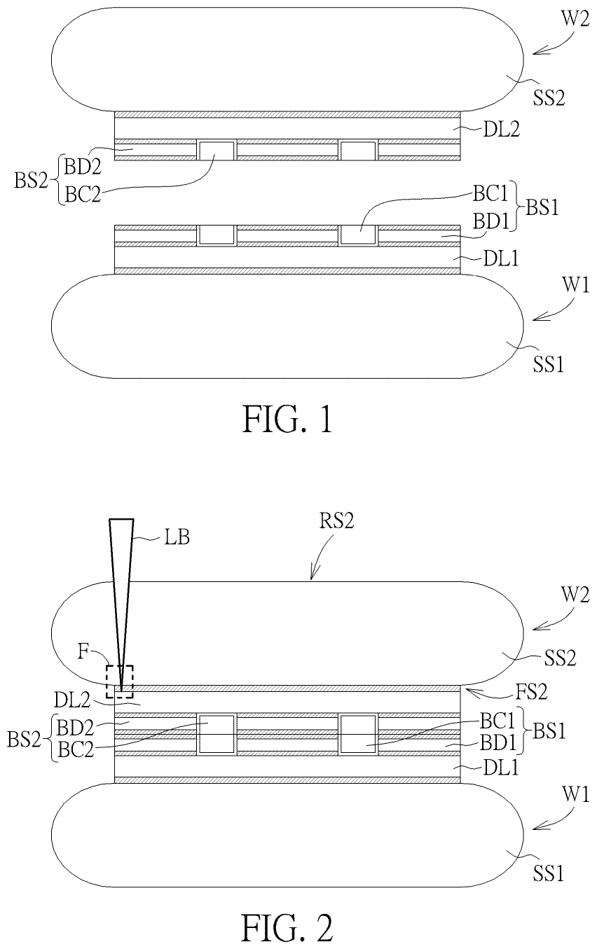

Please refer to FIG. 1 to FIG. 4, which are schematic diagrams showing a wafer processing method according to an embodiment of the present invention. As shown in FIG. 1, a first wafer W1 and a second wafer W2 are provided, and a hybrid bonding process is performed to bond the second wafer W2 to the first wafer W1. According to an embodiment of the present invention, the first wafer W1 includes, for example, a semiconductor substrate SS1, a circuit element layer DL1 formed on the semiconductor substrate SS1, and a bonding layer BS1 formed on the circuit element layer DL1. According to an embodiment of the present invention, the second wafer W2 includes, for example, a semiconductor substrate SS2, a circuit element layer DL2 formed on the semiconductor substrate SS2, and a bonding layer BS2 formed on the circuit element layer DL2.

According to an embodiment of the present invention, the bonding layer BS1 may include a plurality of metal patterns BC1 and a dielectric layer BD1 surrounding the plurality of metal patterns BC1. According to an embodiment of the present invention, the bonding layer B2 may include a plurality of metal patterns BC2 and a dielectric layer BD2 surrounding the plurality of metal patterns BC2. For example, the plurality of metal patterns BC1 and the plurality of metal patterns BC2 may be copper metal patterns, and the dielectric layer BD1 and the dielectric layer BD2 may be silicon dioxide, but are not limited thereto. When performing the above-mentioned hybrid bonding process, the plurality of metal patterns BC1 are respectively aligned with the plurality of metal patterns BC2 and directly bonded together.

As shown in FIG. 2 and FIG. 3, after the second wafer W2 is bonded to the first wafer W1 using a hybrid bonding process, a stealth laser dicing process is performed by using a laser beam LB to focus on an area F adjacent to the front surface FS2 of the second wafer W2, thereby forming an undercut region UC along the perimeter of the front surface FS2 of the second wafer W2. The laser beam LB irradiates the rear surface RS2 of the second wafer W2, and the undercut region UC can be formed at a desired position and depth by controlling the energy and pulse of the laser beam LB.

According to an embodiment of the present invention, for example, the undercut region UC may be a continuous annular area. According to an embodiment of the present invention, for example, the undercut region UC may partially extend into the circuit element layer DL2, but is not limited thereto. According to an embodiment of the present invention, for example, the cross-sectional width w of the undercut region UC is less than 2.8 mm. According to an embodiment of the present invention, for example, the cross-sectional width w of the undercut region UC is 10-200 micrometers, and the cross-sectional length h is 20-200 micrometers.

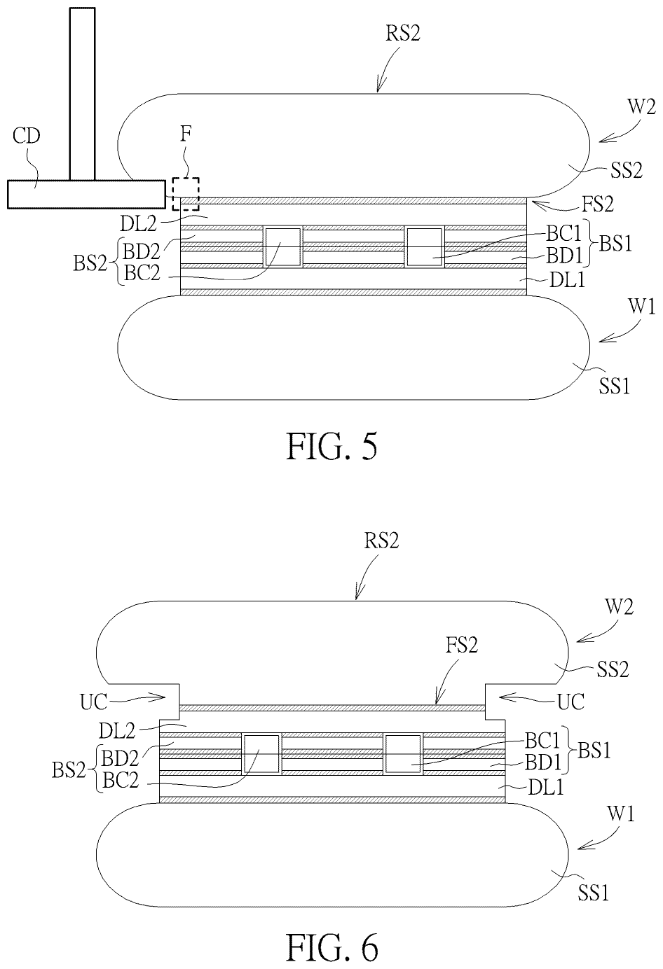

According to another embodiment of the present invention, please refer to FIG. 5 to FIG. 6, the undercut region UC can be formed by performing a lateral wafer edge cutting process. According to an embodiment of the present invention, the above-mentioned lateral wafer edge cutting process uses a diamond blade CD to cut the area F adjacent to the front surface FS2 of the second wafer W2, so that an undercut region UC is formed around the front surface FS2 of the second wafer W2.

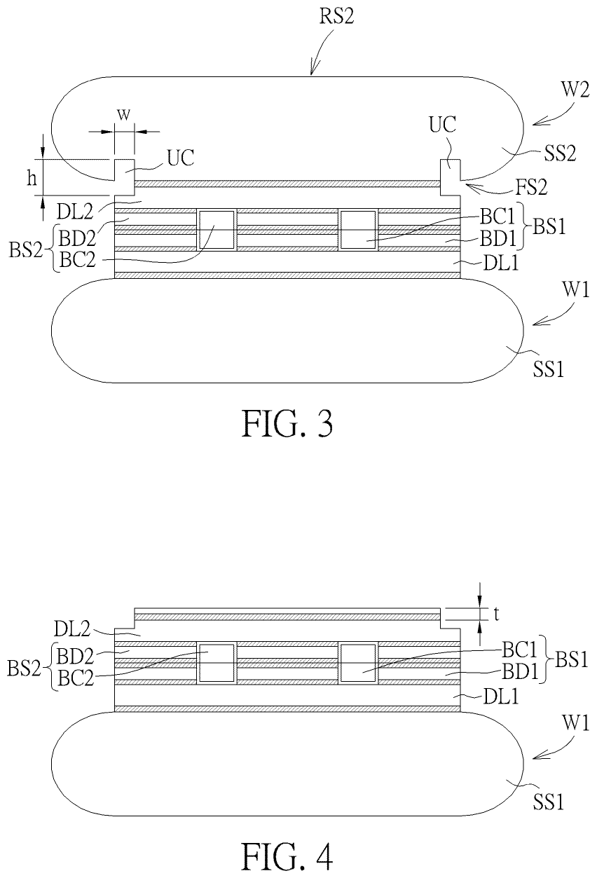

As shown in FIG. 4, a grinding process, such as a chemical mechanical polishing (CMP) process, is then performed on the rear surface RS2 of the second wafer W2, thereby thinning the second wafer W2 to a predetermined thickness t, where the predetermined thickness t is less than 100 micrometers. According to an embodiment of the present invention, the predetermined thickness t is, for example, 30-70 microns.

Compared with the prior art, the present invention is more simplified in steps, can avoid the problem of particulate contamination, and can have a higher yield. In addition, using stealth laser cutting or lateral wafer edge cutting to form a smaller undercut region can reduce the problem of wafer edge chipping and enable a single wafer to produce more good dies.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wafer processing method, comprising:
bonding a second wafer to a first wafer;
forming an undercut region along a periphery of a front surface of the second wafer; and
subjecting a rear surface of the second wafer to a grinding process, thereby thinning the second wafer to a pre-determined thickness.

2. The wafer processing method according to claim 1, wherein the undercut region has a width of less than 2.8 mm.

3. The wafer processing method according to claim 2, wherein the undercut region has a sectional width of 10-200 micrometers.

4. The wafer processing method according to claim 2, wherein the undercut region has a sectional length of 20-200 micrometers.

5. The wafer processing method according to claim 1, wherein the undercut region is formed by performing a stealth laser dicing process.

6. The wafer processing method according to claim 5, wherein a laser beam used during the stealth laser dicing process is focused at a region adjacent the front surface of the second wafer, thereby forming the undercut region.

7. The wafer processing method according to claim 1, wherein the undercut region is formed by performing a lateral wafer edge cutting process.

8. The wafer processing method according to claim 7, wherein the lateral wafer edge cutting process uses a diamond blade to cut the periphery of the front surface of second wafer.

9. The wafer processing method according to claim 1, wherein the second wafer is bonded to the first wafer through hybrid bonding.

10. The wafer processing method according to claim 1, wherein the pre-determined thickness is less than 100 micrometers.
